(19) United States
(12) Patent Application Publication
(10) Pub. No.: US 2017/0343893 A1
(43) Pub. Date: Nov. 30, 2017

(54) DESIGN AND FABRICATION OF PARTIALLY TRANSPARENT PETALED MASK OR OCCULTER USING GRAYSCALE LITHOGRAPHY

(71) Applicant: U.S.A. as represented by the Administrator of the National Aeronautics and Space Administration, Washington, DC (US)

(72) Inventors: Shahram Shiri, Glyndon, MD (US); Jeffrey C. Livas, Severna Park, MD (US)

(21) Appl. No.: 15/164,482

(22) Filed: May 25, 2016

(51) Int. Cl. G03F 1/50; G03F 7/20

(52) U.S. Cl. CPC G03F 1/50; G03F 7/20

(57) ABSTRACT

A mask for Poisson spot suppression includes a plurality of petals equally spaced in a circular pattern, the petals comprising a gray scale lithography substrate, the substrate having an opaque center portion and a gradient of increasing transparency extending toward a perimeter of the circular pattern, the gradient effected by a gray scale lithography process.

### INVENTION BY GOVERNMENT EMPLOYEE(S) ONLY

The invention described herein was made by one or more employees of the United States Government, and may be manufactured and used by or for the Government for governmental purposes without the payment of any royalties thereon or therefor.

### BACKGROUND

The disclosed embodiments generally relate to suppressing diffracted light along an optical axis of transmission.

The Poisson Spot, a bright spot in the shadow of a circular disk (also referred to as the Spot of Arago), has been a controversial topic in debates about the wave versus particle nature of light since its discovery in 1723 by Miraldi. In 1818, hoping to disprove the conjecture that light is a wave, Simeon Poisson submitted a paper in a scientific competition sponsored by the French Academy of Sciences wherein he deduced the ‘outrageous’ conclusion that if light were a wave, there would be a bright spot in the center of a shadow cast by a round opaque object. Much to his irritation, one of the Academy judges, Dominique Arago, performed the experiment and observed the resulting bright spot at the center of the diffraction pattern. Subsequent interest in this phenomenon appeared to recede, primarily being mentioned only in its historical context.

More recently, interest in the Poisson spot has been revived in a wide variety of dimensions from molecular to terrestrial sizes in the quantum-mechanical wave nature of particles, high-energy laser systems, optical lithography, observations of beam halo, and astronomy. The presence of this bright spot at the molecular level has been used to verify the wave properties of large molecules. In certain annular high-energy laser systems, there are substantial flux levels deposited at inconvenient locations throughout the system; some attempts to solve this problem by simple shadowing techniques are inherently impossible due to the nature of the diffraction process that produces the bright spot. In conventional optical lithography, the presence of the unwelcome bright spot causes a distortion of the original mask pattern during exposure.

As shown in FIG. 1, when using a mask 100 to block an incident beam of light 130 from a source 105, light 110 from the Poisson spot may obscure light 115 from a detectable target of interest 120 impinging on a detector 125. The diffraction geometry may be defined as

$$\frac{1}{F} = \frac{λ z}{{a}^{2}}$$

where F is the Fresnel number, λ is the wavelength of the incident beam 130 from the source 105, z is the distance from the mask 100 to the detector 125, and a is the radius of the mask 100. Various intensity-reduction techniques have been studied using circular transparency (apodized) masks, such as the one shown in FIG. 2, and symmetric binary petaled occulters, such as the one shown in FIG. 3, to reduce the intensity of the light 100 along the optical axis in the shadow. Circular transparency masks may be designed to reduce the optical-axis intensity sufficiently, but for freestanding mask applications, manufacturing a soft-edge smooth circular mask to the required accuracy may be prohibitively difficult and expensive. Conversely, binary petaled masks used as external occulters can be manufactured accurately, but are limited in their ability to achieve the intensity reduction in the desired spectrum range. This limitation arises from the fact that the radius of curvature at the petal tips is correlated to the intensity reduction along the optical axis.

It would be advantageous to develop a mask that overcomes the present disadvantages and effectively suppresses the Poisson spot along the optical axis.

### SUMMARY

The disclosed embodiments are directed to designing and fabricating a partially transparent petaled mask using grayscale lithography.

In at least one embodiment, a mask for Poisson spot suppression includes a plurality of petals equally spaced in a circular pattern, one or more of the petals comprising a gray scale lithography substrate. The substrate may have an opaque center portion and a gradient of increasing transparency extending toward a perimeter of the circular pattern, where the opaque center portion and the gradient is effected by a gray scale lithography process.

The one or more petals may each have a base and a tip extending toward the perimeter of the circular pattern.

The gradient of increasing transparency may be confined to a circularly symmetric region proximate the perimeter.

A radius of the circularly symmetric region may be proportional to a radius of curvature of the petal tips.

The gradient of increasing transparency may begin at a boundary located at approximately 0.785 of a radius of the perimeter of the circular pattern.

The gray scale lithography substrate may include high energy beam sensitive glass.

The gray scale lithography process may include an energy beam exposure process for varying an optical density of the substrate.

In one or more embodiments, a method of Poisson spot suppression includes spacing a plurality of petals equally in a circular pattern, wherein one or more of the petals are formed on a gray scale lithography substrate, providing the substrate with an opaque center portion and a gradient of increasing transparency extending toward a perimeter of the circular pattern, and effecting the opaque center portion and the gradient using a gray scale lithography process.

The method may include forming each of the one or more petals with a base and a tip extending toward the perimeter of the circular pattern.

The method may include using the gray scale lithography process to confine the gradient of increasing transparency to a circularly symmetric region proximate the perimeter.

A radius of the circularly symmetric region may be proportional to a radius of curvature of the petal tips.

The method may further include forming the gradient of increasing transparency beginning at a boundary located at approximately 0.785 of a radius of the perimeter of the circular pattern.

The gray scale lithography substrate may include high energy beam sensitive glass.

The method may still further include exposing the gray scale lithography substrate to an energy beam to effect a varying optical density of the substrate.

### BRIEF DESCRIPTION OF THE DRAWINGS

The foregoing aspects and other features of the embodiments are explained in the following description, taken in connection with the accompanying drawings, wherein:

FIG. 1 shows an exemplary system that generates light from a Poisson spot;

FIG. 2a shows an exemplary circular transparency masks;

FIG. 2b shows an exemplary binary petaled occulter;

FIG. 3 shows a plot of intensity along an optical axis as a function of a reciprocal of a Fresnel number for an exemplary petaled mask;

FIG. 4 shows a plot of intensity along an optical axis as a function of a reciprocal of a Fresnel number for three exemplary partially transparent circular masks;

FIGS. 5a-5d show exemplary hybrid masks according to the disclosed embodiments;

FIG. 6 shows exemplary transparency function profiles for the masks in FIGS. 5a-5d;

FIG. 7 shows exemplary intensity reductions as a function of a reciprocal of a Fresnel number along an optical axis for the masks in FIGS. 5a-5d;

FIG. 8 shows an exemplary partially transparent petaled mask according to the disclosed embodiments;

FIG. 9 shows a comparison of intensity reductions achieved by different types of masks;

### DETAILED DESCRIPTION

The disclosed embodiments are directed to designing and fabricating a partially transparent petaled mask or occulter using grayscale lithography.

The terms “mask” and “occulter” are used interchangeably throughout this application. In certain aspects, the terms “mask” and “occulter” may be differentiated by manufacturing or fabrication methods, where a “mask” may be fabricated on a medium such as glass or silicon, while an “occulter” may be a free standing medium that may be manufactured using, for example, a 3D printer, electrical discharge machining, or other suitable machine or process. It should be understood that for the purposes of the present application, the descriptions, principles, structures, and techniques described herein are applicable to both masks and occulters.

The term “partially transparent” may include a radially tapered or gradient transparency with an increase in transparency toward a mask perimeter.

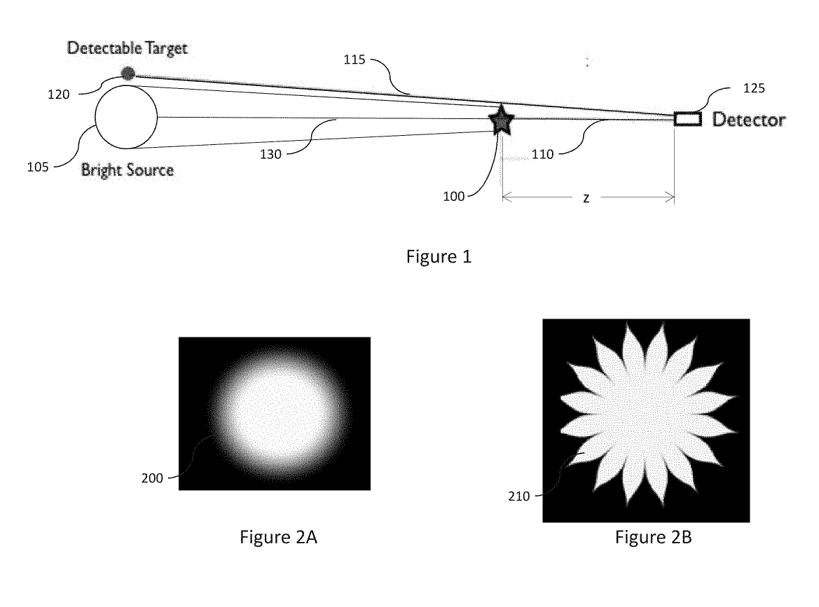

To abolish the bright spot, the disclosed embodiments are directed to one or more partially transparent masks designed to determine a geometry and transmission properties that achieve an intensity reduction in a desired spectrum range while being practical to manufacture. A design process has been established where suppression requirements are used as constraints of an optimization algorithm to shape a transparency profile of a mask. A physical-optics analysis is developed of a petal-shaped boundary having partial transparency at the petal ends to suppress the intensity along the optical axis. This novel class of masks allows the radii of curvature at the petal ends to be increased to physically realizable values while maintaining significant levels of intensity reduction. The formulation has been developed within the parameters of the near-field diffraction geometry as shown in FIG. 1, where the Fresnel number, F=R²/(λz), is much greater than one. In this notation, R is the radius of the mask, λ is the wavelength of the incident beam 130 from the source, and z is the distance between the mask and detector.

The field in the shadow zone of a mask may be expressed by:

E_{y}(ρ,z)=Ae^{-ik}^{ₒ}^{z}−A∫₀^{2π} dφ∫₀^{R(φ)}[1−T(ρ═)]ρ′ dρ′×∫_{-∞}^{+∞}∫_{-∞}^{+∞}e^{-k}^{ᵢ}^{(ρ′-ρ)}d²kₜ (1)

and the corresponding relative intensity by:

$$I ( ρ , z ) = \frac{{\vert {E}_{y} ( ρ , z ) \vert}^{2}}{{A}^{2}} \qquad ( 2 )$$

The first term on the right of equation (1) is the field of an incident plane wave from the source and the second term, the scattered field caused by the mask; p is the radius in the observation coordinates (ρφ) normal to the z-axis, T(ρ′) is the transparency function, which depends only on the distance from the coordinate center, and R(φ′) is the functional form of the mask boundary. It can be shown that, along the optical axis, the general expression (1) for the field can simplify to:

$${E}_{y} ( ρ , z ) = \frac{A}{2 π} {\int }_{0}^{2 π} d {ϕ}^{′} \{ 1 - T [ R ( {ϕ}^{′} ) ] \} \frac{{ze}^{- {ik}_{0} \sqrt{{z}^{2} + {R ( {ϕ}^{′} )}^{2}}}}{\sqrt{{z}^{2} + {R ( {ϕ}^{′} )}^{2}}} d {ρ}^{′} + \frac{A}{2 π} {\int }_{0}^{2 π} d {ϕ}^{′} {\int }_{0}^{R ( {ϕ}^{′} )} d {ρ}^{′} d {ρ}^{′} \frac{ϑT ( {ρ}^{′} )}{{ϑρ}^{′}} \times \frac{{ze}^{- {ik}_{0} \sqrt{{z}^{2} + {{ρ}^{′}}^{2}}}}{\sqrt{{z}^{2} + {{ρ}^{′}}^{2}}} \qquad ( 3 )$$

In this form, the incident field from the source together with the scattered field caused by the mask may be merged into a single integral representation. Also, because the intensity of incident and scattered fields in the shadow of the mask can differ by several orders of magnitude or more, the representation in equation (3) has distinct computational advantages over equation (1), where the incident and scattered fields have to be subtracted directly. In addition, the contribution arising from the variation of the transparency function with the radial coordinate can be identified directly with the second term on the right containing the derivative. For a totally opaque structure, this term vanishes and, in addition, T(ρ′)=0. In this case, for a mask with a general contour R(φ′), equation (3) reduces to:

$${E}_{y} ( 0 , z ) = \frac{A}{2 π} {\int }_{0}^{2 π} d {ϕ}^{′} \frac{{ze}^{- {ik}_{0} \sqrt{{z}^{2} + {R ( {ϕ}^{′} )}^{2}}}}{\sqrt{{z}^{2} + {R ( {ϕ}^{′} )}^{2}}} \qquad ( 4 A )$$

from which the field in the shadow on the optical axis of a petaled mask, and of a constant-radius disk (yielding the Poisson-spot intensity) follow as special cases.

Using the Green's function, equation (3) may also reduce to:

$${E}_{y} ( 0 , z ) = A {\int }_{0}^{R} \frac{{ze}^{- {ik}_{0} \sqrt{{z}^{2} + {ρ}^{2}}}}{\sqrt{{z}^{2} + {ρ}^{2}}} \frac{dT ( {ρ}^{′} )}{d {ρ}^{′}} d {ρ}^{′} \qquad ( 4 B )$$

For points off the optical axis, a single representation incorporating the incident and scattered fields appears more difficult to construct. However a substantially simpler form, more amenable to computation than direct use of equation (1), is still possible. According to the principles of physical optics, equation (1) can be transformed into:

$${E}_{y} ( ρ , z ) = A \{ {e}^{- {ik}_{o} z} - \frac{- {ik}_{0}}{2 π z} {e}^{- {ik}_{o} z} {e}^{- {ik}_{o} \frac{{ρ}^{2}}{2 z}} \times {\int }_{0}^{2 π} d {ϕ}^{′} {\int }_{0}^{R ( {ϕ}^{′} )} [ 1 - T ( {ρ}^{′} ) ] {ρ}^{′} {e}^{- {ik}_{o} \frac{{ρ}^{2}}{2 z}} \times {e}^{- {ik}_{o} \frac{{ρρ}^{′} cos ( ϕ - {ϕ}^{′}}{z}} d {ρ}^{′} \} - \qquad ( 5 )$$

involving a double integral instead of a quadruple integral. As a simplification, equation (5) uses the Fresnel approximation that is valid for the parameter range of interest herein. This approximation was not introduced earlier, in equation (3), because for this particular set of parameters, it would not have provided any computational advantages. One can show that, along the optical axis, equation (5) is identical to the Fresnel approximation of equation (3).

The intensity reductions achieved using a partially transparent circular mask 200 (FIG. 2a) and a totally opaque petaled mask 210 (FIG. 2b) may be compared. The radially tapered transparency mask 200 as shown in FIG. 2a does not have petals and the functional form of the transparency has been chosen to minimize the average intensity over a prescribed interval of the optical axis; the designs of these masks were made based on a physical optics derivation methodology outlined in Wasylkiwskyj W. and Shiri S., Limits on Achievable Intensity Reduction with an Optical Occulter, Journal of the Optical Society of America A. 2011, pp. 1668-1678, Vol. 28, No. 8, incorporated by reference in its entirety.

The field in the mask shadow is evaluated using equation (4A) for the totally opaque petal mask 210 and equation (4B) for the partially transparent circular mask 200.

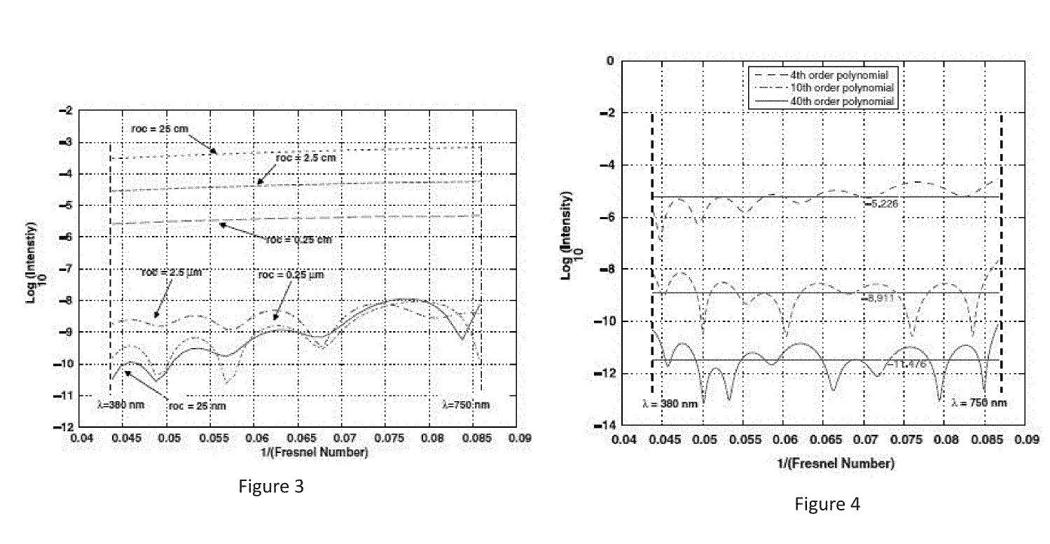

FIG. 3 shows a plot of the intensity along the optical axis as a function of the reciprocal of the Fresnel number for a mask with six totally opaque petals designed for a visible range spectrum. As the radius of curvature (roc) of the petal tips is progressively reduced from 25 cm to 25 nm, the intensity continues to decrease. It should be noted that the results of FIG. 3 predict that reaching a ten orders of magnitude reduction would require radii of curvature in the nanometer range, however, diffraction from such small structures by visible-wavelength light is beyond the domain of physical optics, making implementation of these results impractical. In the μm and mm range, which may be within the domain of physical optics, an intensity reduction of ten orders of magnitude appears to be unachievable.

FIG. 4 shows a plot of the intensity along the optical axis as a function of the reciprocal of the Fresnel number for three partially transparent circular masks, differing in the order of the polynomial in the transparency function using equation (2). It should be noted that as the order of the partial-transparency function polynomial is increased, the achievable intensity reduction also increases until the polynomial order reaches a maximum (in the present case 40) identified by the threshold in the associated singular value decomposition as described in Wasylkiwskyj W. and Shiri S., incorporated by reference above. For this polynomial order, the intensity reduction may be comparable to that of the petal-style mask in FIG. 3 where the tip radii of curvature are reduced to the nanometer range where diffraction by visible-wavelength light may be beyond the domain of physical optics.

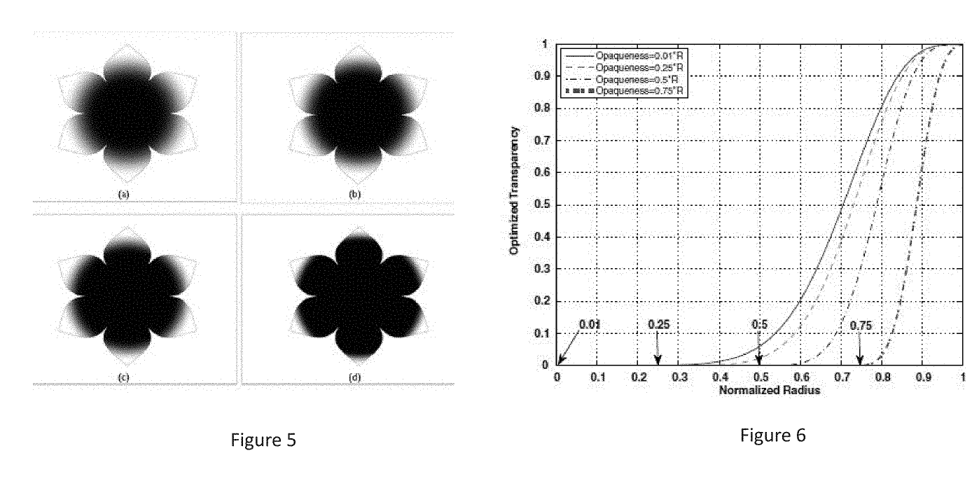

In order to overcome the requirement of physically unrealizable tip radii of curvature and a partial transparency that must cover the entire disk, the disclosed embodiments are directed to a petal-style geometry incorporated together with a gradient transparency into a class of hybrid masks, where the graded transparency may be confined to a circularly symmetric outer region of the mask as shown in FIGS. 5a-5d. The key trade-off in this class of masks is that decreasing the radius of the opaque circular portion of the mask permits a proportional increase of the radii of curvature at the petal tips. In the limit when the radius of the opaque inner circle in the mask approaches the outer mask radius, the tip radii curvature all degenerate to the outer disk radius and the transparency covers the entire disk. In the ‘opposite’ limit, as the diameter of the inner circle is allowed to approach zero, we obtain the classic petal-style opaque mask with sharp petal tips. Thus, the radius of the opaque circular portion of the mask and the radii of curvature at the petal tips are proportional. FIG. 5(a) shows opacity at 0.01R, of the normalized disk radius, while FIGS. 5(b)-(d) show opacity at 0.25R, 0.50R, and 0.75R respectively of the normalized disk radius. While each petal of the exemplary masks of FIGS. 5a-5d are shown with a gradient transparency, it should be understood that one or more opaque petals or other structures may be interposed with one or more petals having a gradient transparency.

The transparency-function profile associated with the masks of FIGS. 5(a)-(d), where the ‘offset’ shifts the beginning of the transparency, is derived using equations (4A) and (4B) and depicted in FIG. 6. The transparency profile shown in FIG. 6 is not only shifted to larger normalized radii, but its general S-curve shape is altered due to the introduction of the ‘offset’ bias and optimization algorithm. Note that the slope of these transparency curves increases as the opacity is increased. The profile representing the smallest region of opacity (0.01R) is symbolically confined to a small region at the center to satisfy the assumption that transparency is zero at the center of the disk. The profile with the offset set at 0.75R apparently has the sharpest slope. The radii of curvature of the six-petal shape have been arbitrarily chosen to be 25 cm.

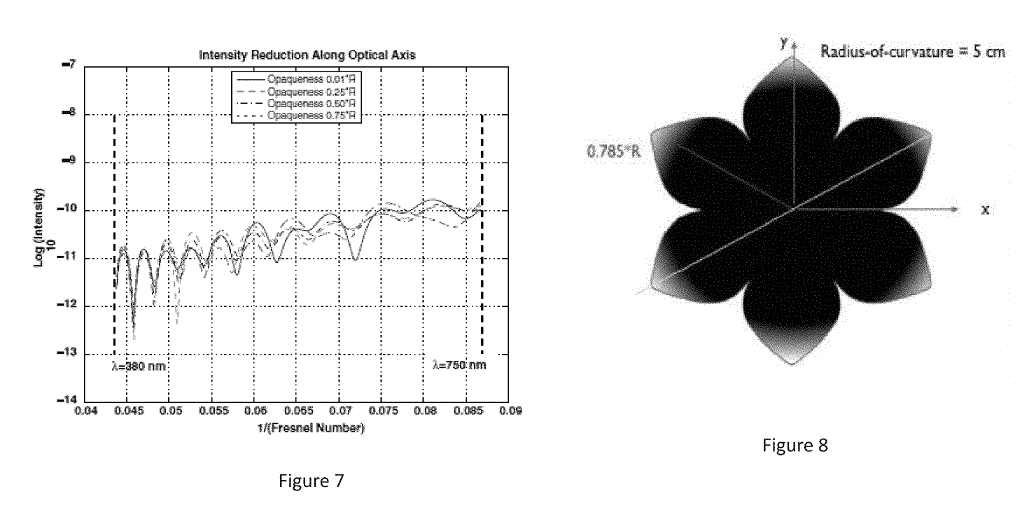

The intensity reduction along the optical axis associated with these transparency profiles is shown in FIG. 7. The location of the offset does not improve the intensity reduction substantially.

The changes in the opacity within the range of 0.75R do not improve the intensity reduction along the optical axis substantially. As a result, to better fabricate and manufacture such a mask, it is advantageous to obtain the optimized ‘offset’ position furthest away from the center of the disk. This observation implies an opacity covering a larger area of the disk, where only a small portion of the petal ends has a graduated transparency. Based on these results, the optimum transparency profile with the six petals occurs around 0.785R. The general shape of such a mask is shown in FIG. 8.

For the six-petal mask with full opacity covering 0.785R of the radius, the petal tip radii could be adjusted from 50 μm to as large as 50 cm, and for each choice of tip radii, the partial transparency near the petal ends can be adjusted to provide an optimized mask that significantly reduces the intensity along the optical axis. The area covered by the transparent portion of this mask is about 2% of the area of the circular disk. Compared with the fully transparent circular disk, this ratio represents significant reductions in the area that must be covered by a transparency and should substantially reduce the challenges to fabricate such masks.

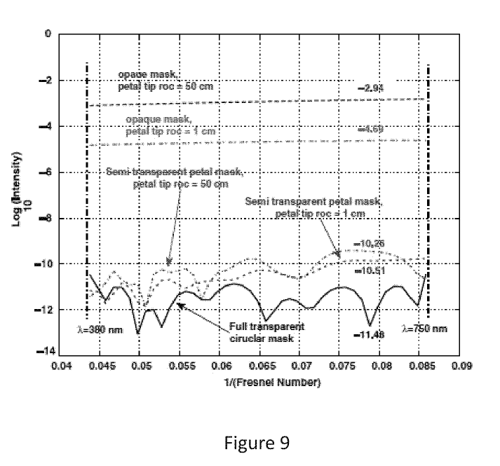

It is important to note that the relative intensity does not depend explicitly on the radius of the disk or the distance between the disk and the observation point, but only on the reciprocal of the Fresnel number at the observation point. According to the disclosed embodiments, the intensity is calculated numerically using Gaussian quadrature and employ high-resolution interpolation points between the fixed Legendre polynomial intervals with equal weighting functions. FIG. 9 compares the intensity reduction due to totally opaque petaled masks with different radius of curvatures, semi-transparent or graded transparency petaled masks with different radius of curvatures, and a partially transparent circular mask, along the optical axis for light in the visible spectrum.

The plots at the top of FIG. 9 represent the intensity reduction obtained by opaque six-petal masks with radii of curvature of 50 cm and 1 cm. The average intensity reduction in these cases is −2.94 and −4.69 orders of magnitude, respectively. The partially transparent circular mask, using a 40th order polynomial for the transparency function, shows the best performance. Closely following is the performance of the two partially transparent petaled masks. The optimized transparency in both cases has an ‘offset’ of 0.785R. The masks with 5 cm petal tip radii of curvature yield a mean log-intensity reduction of approximately −10.26 and the mask with 1 cm tip radii of curvature has a reduction of approximately −10.51. We should note the lack of sensitivity of this reduction to changes in the radii of curvature. By comparison, the same change in the radii of curvature in the totally opaque petal-style mask changes the intensity by about two orders of magnitude.

A fabrication process is required that produces masks that, when actually manufactured, match the intended design. A grayscale lithography process may be an example of a process suitable for mask manufacturing. For example, a gray scale lithography process utilizing an energy beam applied to High Energy Beam Sensitive (HEBS) glass may be used because it provides accurate grayscale gradation as well as a precise outline of the petals. Various types of energy beams may be used to activate the greyscale lithography process within the glass including molecular beams, x-ray beams, ion beams, electron beams, laser beams and various wavelengths of ultraviolet light. For example, partially transparent petaled mask fabrication could utilize a vector scan element beam using an approximately 0.1 micron addressing grid size in high-energy beam sensitive glass to pattern at least 100 gray levels i.e. 100 concentric rings, where each ring is 50 microns. Suitable HEBS glass substrates may include low expansion zinc-borosilicate glass doped with silver ions.

The design process for the partially transparent petaled mask may be highly dependent on a number of parameters specific to the application. As an example, the wavelength of the incident beam and distance between the detector and secondary mirror play an important role in the expected Fresnel Number calculation.

Various applications may include detecting and measuring gravitational waves from astronomical forces, high-energy laser systems, optical lithography, and observation of beam halo. For example, when used in measuring gravitational waves from astronomical forces, the laser source reflection from a secondary mirror of an on-axis telescope and its interference on the detector can be characterized as near-field propagation where the radius of the occulting mask significantly affects other design parameters. The design process may be optimized for a particular Fresnel Number of the on axis telescope, for example, 4.7. Other applications may include planet location missions that may require suppression of direct starlight by at least 10 orders of magnitude.

It is noted that the embodiments described herein can be used individually or in any combination thereof. It should be understood that the foregoing description is only illustrative of the embodiments. Various alternatives and modifications can be devised by those skilled in the art without departing from the embodiments. Accordingly, the present embodiments are intended to embrace all such alternatives, modifications and variances that fall within the scope of the appended claims.

1. A mask for Poisson spot suppression comprising:
a plurality of petals equally spaced in a circular pattern, one or more of the petals comprising a gray scale lithography substrate;
the substrate having an opaque center portion and a gradient of increasing transparency extending toward a perimeter of the circular pattern, the opaque center portion and the gradient effected by a gray scale lithography process.

2. The mask of claim 1, wherein the one or more petals each comprise a base and a tip extending toward the perimeter of the circular pattern.

3. The mask of claim 1, wherein the gradient of increasing transparency is confined to a circularly symmetric region proximate the perimeter.

4. The mask of claim 3, wherein a radius of the circularly symmetric region is proportional to a radius of curvature of the petal tips.

5. The mask of claim 3, wherein the gradient of increasing transparency begins at a boundary located at approximately 0.785 of a radius of the perimeter of the circular pattern.

6. The mask of claim 1, wherein the gray scale lithography substrate comprises high energy beam sensitive glass.

7. The mask of claim 1, wherein the gray scale lithography process comprises an energy beam exposure process for varying an optical density of the substrate.

8. A method of Poisson spot suppression comprising:
spacing a plurality of petals equally in a circular pattern, wherein one or more of the petals are formed on a gray scale lithography substrate;
providing the substrate with an opaque center portion and a gradient of increasing transparency extending toward a perimeter of the circular pattern; and
effecting the opaque center portion and the gradient using a gray scale lithography process.

9. The method of claim 8, comprising forming each of the one or more petals with a base and a tip extending toward the perimeter of the circular pattern.

10. The method of claim 8, comprising using the gray scale lithography process to confine the gradient of increasing transparency to a circularly symmetric region proximate the perimeter.

11. The method of claim 10, wherein a radius of the circularly symmetric region is proportional to a radius of curvature of the petal tips.

12. The method of claim 10, comprising forming the gradient of increasing transparency beginning at a boundary located at approximately 0.785 of a radius of the perimeter of the circular pattern.

13. The method of claim 8, wherein the gray scale lithography substrate comprises high energy beam sensitive glass.

14. The method of claim 8, comprising exposing the gray scale lithography substrate to an energy beam to effect a varying optical density of the substrate.
